(19) United States
(12) Patent Application Publication
(10) Pub. No.: US 2019/0169742 A1
(43) Pub. Date: Jun. 6, 2019

(54) GAS PIPING SYSTEM, CHEMICAL VAPOR DEPOSITION DEVICE, FILM DEPOSITION METHOD, AND METHOD FOR PRODUCING SiC EPITAXIAL WAFER

(71) Applicant: SHOWA DENKO K.K., Tokyo (JP)

(72) Inventors: Naoto ISHIBASHI, Chichibu-shi (JP); Keisuke FUKADA, Chichibu-shi (JP); Tomoya UTASHIRO, Chichibu-shi (JP); Akira BANDO, Hiki-gun (JP)

(73) Assignee: SHOWA DENKO K.K., Tokyo (JP)

(21) Appl. No.: 16/314,084

(22) PCT Filed: Jun. 12, 2017
(86) PCT No.: PCT/JP2017/021604

§ 371 Date: Dec. 28, 2018

(30) Foreign Application Priority Data
Jul. 7, 2016 (JP) 2016-135282

(51) Int. Cl. C23C 16/455; C23C 16/32; C30B 29/36; C30B 25/14; H01L 21/02

(52) U.S. Cl. CPC C23C 16/455; C23C 16/325; H01L 21/0262; C30B 25/14; H01L 21/02529; C30B 29/36

(57) ABSTRACT

This gas piping system is a run-vent mode gas piping system in which, the gas piping system including a plurality of supply lines through which plural gases are fed individually, an exhaust line that leads from a reactor to an exhaust pump, a run line having one or plural pipes which respectively branch from the plural supply lines, plural vent lines which respectively branch from the supply lines and are connected to the exhaust line, and plural valves which are respectively provided at the branch points of the plural supply lines, and switches between feeding a gas to the run line side and feeding a gas to the vent line side, wherein the plural vent lines are separated from each other until the vent lines reach the exhaust line, and the inner diameter of the exhaust line is greater than the inner diameter of the plural vent lines.

### TECHNICAL FIELD

The present invention relates to a gas piping system, a chemical vapor deposition device, a film deposition method, and a method for producing a SiC epitaxial wafer. Priority is claimed on Japanese Patent Application No. 2016-135282, filed Jul. 7, 2016, the content of which is incorporated herein by reference.

### BACKGROUND ART

Silicon carbide (SiC) has superior properties when compared with silicon (Si), and holds much promise for applications to power devices, high-frequency devices, and high-temperature operation devices and the like. For example, the dielectric breakdown electric field of SiC is an order of magnitude larger than that of Si, the band gap of SiC is three times as wide as that of Si, and the thermal conductivity of SiC is about three times higher than that of Si. As a result, in recent years, SiC epitaxial wafers are attracting much attention as substrates for semiconductor devices.

SiC epitaxial wafers are produced by using a chemical vapor deposition (CVD) method to grow a SiC epitaxial layer, which functions as the active region of a SiC semiconductor device, on a SiC single crystal substrate.

When growing a SiC epitaxial layer, raw material gases, a dopant gas, an etching gas, and a carrier gas and the like are supplied to the reactor of the chemical vapor deposition device. For example, Patent Document 1 discloses the use of ammonia as a dopant gas. Further, Patent Document 2 discloses the use of hydrogen chloride as an etching gas and a chlorosilane as a raw material gas.

Furthermore, in order to enhance the performance of the semiconductor device, a high-quality epitaxial wafer having superior crystallinity for the deposited epitaxial layer is desirable. One known technique for stably producing high-quality epitaxial layers is the run-vent mode gas piping system disclosed in Patent Document 3. In a gas piping system using the run-vent mode, fluctuations in the flow velocity and pressure of the gases introduced into the reactor can be suppressed, meaning gas disturbances at the crystal growth surface can be suppressed.

### PRIOR ART LITERATURE

### Patent Documents

Patent Document 1: Japanese Unexamined Patent Application, First Publication No. 2006-261612

Patent Document 2: Japanese Unexamined Patent Application, First Publication No. 2006-321696

Patent Document 3: Japanese Unexamined Patent Application, First Publication No. H04-260696

### SUMMARY OF THE INVENTION

### Problems to be Solved by the Invention

However, even when an aforementioned run-vent mode chemical vapor deposition device is used, problems arise such that the reproducibility of the obtained epitaxial layers tends to deteriorate over time, and/or a deterioration in the crystallinity is caused and therefore it becomes difficult to obtain high-quality films in a stable manner.

It is thought that this problem occurs due to the variety of gases being supplied to the reactor. The gases that are supplied to the reactor may sometimes include combinations of gases (hereafter referred to as deposit-causing gases) which react together at normal temperatures to produce solid products.

For example, during SiC epitaxial growth, if hydrogen chloride or a chlorosilane is used at the same time with ammonia, then ammonium chloride is formed, and deposits are produced. These types of deposits can cause blockages of the gas piping.

The present disclosure has been developed in light of the above problems, and has an object of providing a gas piping system in which blockages of the pipes are suppressed.

### Means for Solving the Problems

Because a run line which feeds a gas into the reactor is a pipe through which a gas being supplied to the reactor flows, the probability of a run line having a direct effect on crystal growth is high, and therefore consideration has been given to ensure that blockages and the like do not occur. However, a vent line connected to the exhaust side is not used for supplying a gas to the reactor, and because the probability of a vent line having any direct effects is low, little attention has been paid to vent lines.

As a result of undertaking intensive investigations against a background of this type of conventional thinking, the inventors of the present disclosure focused their efforts on the exhaust-side vent lines. As a result, they discovered that by disposing the vent lines separately, blockages of the vent lines could be suppressed. As a result, they discovered that the occurrence of differences in the gas flow velocity and gas pressure between the run line and the vent lines could be suppressed, and the degree of freedom associated with setting the conditions during crystal growth could be enhanced.

In other words, in order to achieve the object described above, the present disclosure provides the following aspects.

(1) A gas piping system according to the first aspect is a run-vent mode gas piping system in which a plurality of gases are supplied to an inside of a reactor which vapor deposition is performed, the gas piping system including a plurality of supply lines through which the plurality of gases are fed individually, an exhaust line that leads from an exhaust port of the reactor to an exhaust pump, a run line which has one or a plurality of pipes which respectively branch from the plurality of supply lines to supply the plurality of gases to the reactor, a plurality of vent lines which respectively branch from the plurality of supply lines and are connected to the exhaust line, and a plurality of valves which are respectively provided at branch points of the plurality of supply lines, and switches between feeding a gas to the run line side and feeding a gas to the vent line side, wherein the plurality of vent lines are separated from each other until the vent lines reach the exhaust line, and the inner diameter of the exhaust line is greater than the inner diameter of each of the plurality of vent lines.
(2) In the run line of the gas piping system according to the aspect described above, the pipes, which connect with the branch points, may have a configuration in which the pipes join together before the pipes reach the reactor.
(3) The gas piping system according to the aspect described above may have a configuration in which, among the plurality of vent lines, at least one vent line is connected to the exhaust line, and the remaining vent lines are each connected to a separate exhaust pump which is provided independently.
(4) In the gas piping system according to the aspect described above, the pipe inner diameter of the exhaust line may be 3 cm or greater at the connection points where the exhaust line connect with each of the plurality of vent lines.
(5) A chemical vapor deposition device according to the first aspect includes the gas piping system according to the aspect described above, and a reactor that is connected to the gas piping system.
(6) A film deposition method according to the first aspect is a film deposition method that uses the chemical vapor deposition device according to the aspect described above, the method including sending deposit-causing gases, which produce a solid compound upon mutual reaction at normal temperature, through the vent lines which are independent and are mutually separated.
(7) In the film deposition method according to the aspect described above, regarding the exhaust line to which the plurality of vent lines connect, the gas concentration of each of the deposit-causing gases may be 5% or less of that of the total gas which flows through the exhaust line.
(8) A method for producing a SiC epitaxial wafer according to the first aspect is a method for producing a SiC epitaxial wafer using the film deposition method according to the aspect described above, wherein the deposit-causing gases are a basic N-based gas composed of molecules which include an N atom within the molecule but have neither a double bond nor a triple bond between N atoms, and a Cl-based gas composed of molecules which include a Cl atom within the molecule.

### Effects of the Invention

The gas piping system according to the aspect described above can suppress pipe blockages. As a result, the occurrence of differences in the gas flow velocity and gas pressure between the run line and the vent lines of the chemical vapor deposition device can be suppressed, and the degree of freedom associated with setting the conditions during crystal growth can be enhanced.

### BRIEF DESCRIPTION OF THE DRAWINGS

FIG. 1 is a schematic view of a chemical vapor deposition device according to the first embodiment.

FIG. 2 is a schematic view of a chemical vapor deposition device in which the vent lines join together before reaching the exhaust line.

FIG. 3 is a schematic view of a chemical vapor deposition device according to the second embodiment.

FIG. 4 is a schematic view of a chemical vapor deposition device according to the third embodiment.

### EMBODIMENTS FOR CARRYING OUT THE INVENTION

The gas piping system and the chemical vapor deposition device are described below in detail with appropriate reference to the drawings. The drawings used in the following description may sometimes be drawn with specific portions enlarged as appropriate to facilitate comprehension of the features of the present disclosure, and the dimensional ratios and the like between the constituent elements may differ from the actual values. Further, the materials and dimensions and the like presented in the following examples are merely examples, which in no way limit the present disclosure, and may be altered as appropriate within the scope of the present disclosure.

### First Embodiment

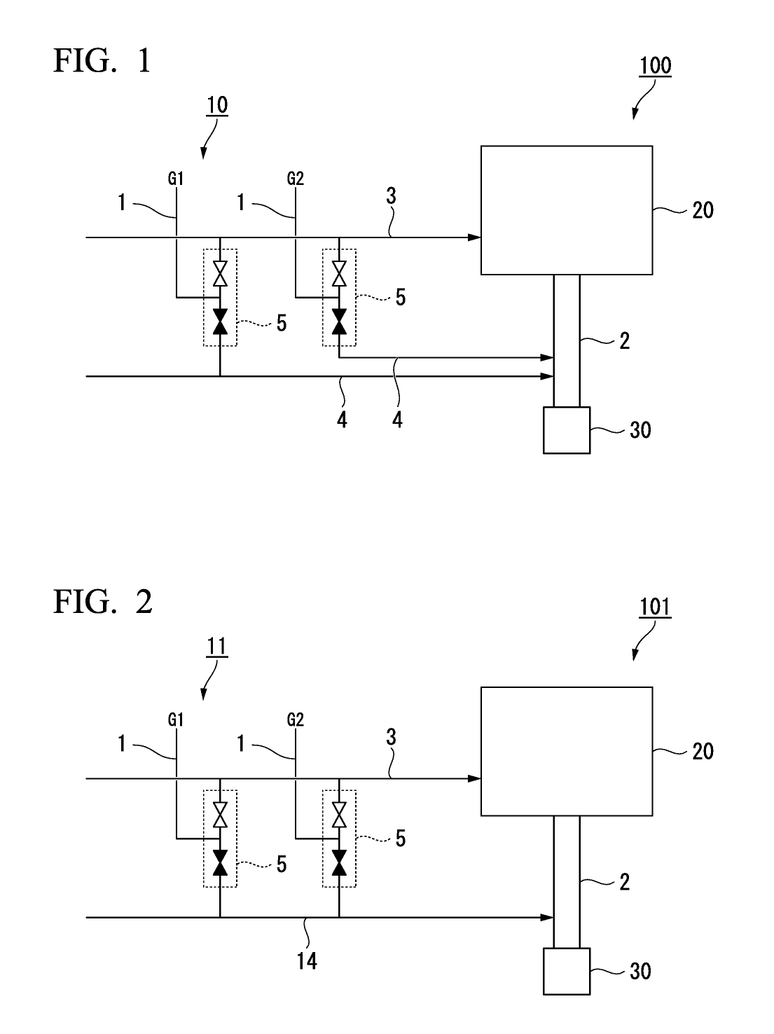

FIG. 1 is a schematic view of a chemical vapor deposition device according to the first embodiment. The chemical vapor deposition device 100 illustrated in FIG. 1 includes a gas piping system 10, a reactor 20, and an exhaust pump 30. A plurality of gases are supplied from the gas piping system 10 to the reactor 20. The reactor 20 and the exhaust pump 30 may use conventional devices.

The gas piping system 10 is a run-vent mode gas piping system that includes supply lines 1, an exhaust line 2, a run line 3, vent lines 4, and valves 5.

A supply line 1 is provided for each of the plurality of gases that are supplied to the reactor 20. One end of each supply line 1 is connected to a gas supply device (omitted from the drawing) such as a gas cylinder.

Each of the supply lines 1 branches into a run line 3 and a vent line 4. A valve 5 that controls the gas flow is provided at each of the branch points.

In the run-vent mode, one valve 5 is provided on each of the run line side and the vent line side, forming a pair of valves. The pair of valves may employ valves of the same type, and are disposed in a symmetrical arrangement as close as possible to the branch point of the supply line 1. A plurality of these types of valve pairs are installed in proximal positions in accordance with the kinds of the various gases that are supplied. Arranging the valves in proximal positions means that when the gases that are supplied in the epitaxial growth process are switched using the valves, any delay that may occur in switching the various supply gases can be reduced to a minimum. A block valve in which this type of plurality of valve pairs have been incorporated into a single block is sometimes used for the valves 5.

These pairs of valves 5 are used such that when a gas is supplied, one of the valves is opened and the other is closed. In other words, the pair of valves 5 are never both open at the same time. For example, by initially opening the vent line side and stabilizing the flow rate, and then simultaneously performing opening of the run line side and closing of the vent line side, fluctuations in the flow rate during valve control that can lead to disturbances in the gas flow rate can be prevented.

The run line 3 connects the valves 5 and the reactor 20. In the run line 3 illustrated in FIG. 1, pipes that branch from each of the supply lines 1 merge at the position of connecting the valves 5 and the reactor 20. In other words, the run line 3 is formed as a single manifold. By forming the run line 3 as a single manifold, the run line side position of each valve 5 can be positioned close to the branch point of the corresponding supply line 1. Arranging the run line side position of each valve 5 close to the branch point of the corresponding supply line 1 means that, as described above, when the gases that are supplied in the epitaxial growth process are switched, any delay that may occur in switching the various supply gases can be reduced to a minimum.

The vent lines 4 connect the valves 5 and the exhaust line 2. The exhaust line 2 is a pipe that links the exhaust port of the reactor 20 and the exhaust pump 30. The vent lines 4 that branch from the various supply lines 1 are separated until reaching the exhaust line 2. Accordingly, no mixing of the gases flowing through the vent lines 4 occurs until the vent lines 4 reach the exhaust line 2.

The piping used for the supply lines 1, the exhaust line 2, the run line 3 and the vent lines 4, and the switching valves used for the valves 5 may employ conventional pipes and valves.

The gas flow through the chemical vapor deposition device 100 is described below using the case where a SiC epitaxial wafer is produced inside the reactor 20 as an example.

First is a description of the gases used during crystal growth of the SiC epitaxial wafer. During crystal growth of the SiC epitaxial wafer, a plurality of gases are used, including raw material gases, a dopant gas, an etching gas, and a carrier gas.

In this description, the plurality of gases which can be used during crystal growth of the SiC epitaxial wafer are classified into 6 groups, namely “Si-based gases”, “C-based gases”, “Cl-based gases”, “N-based gases”, “other impurity doping gases” and “other gases”.

A “Si-based gas” is a gas that includes Si as a compositional element of the molecules that constitute the gas.

Examples thereof include silane (SiH₄), dichlorosilane (SiH₂Cl₂), trichlorosilane (SiHCl₃) and tetrachlorosilane (SiCl₄). The Si-based gas is used as one of the raw material gases.

A “C-based gas” is a gas that includes C as a compositional element of the molecules that constitute the gas. Examples thereof include propane (C₃H₈). The C-based gas is used as one of the raw material gases.

A “Cl-based gas” is a gas that includes Cl as a compositional element of the molecules that constitute the gas.

Examples thereof include hydrogen chloride (HCl), dichlorosilane (SiH₂Cl₂), trichlorosilane (SiHCl₃) and tetrachlorosilane (SiCl₄). Dichlorosilane (SiH₂Cl₂), trichlorosilane (SiHCl₃) and tetrachlorosilane (SiCl₄) can also be classified as aforementioned Si-based gases. As these gases illustrate, a gas may sometimes be both a “Cl-based gas” and a “Si-based gas”. The “Cl-based gas” is used as a raw material gas or an etching gas.

An “N-based gas” is a gas that includes N as a compositional element of the molecules that constitute the gas, and is a basic gas composed of molecules which have neither a double bond nor a triple bond between N atoms. Examples thereof include gases selected from the group consisting of methylamine (CHsN), dimethylamine (C₂H₇N), trimethylamine (C₃H₉N), aniline (C₆H₇N), ammonia (NH₃), hydrazine (N₂H₄), dimethylhydrazine (C₂H₅N₂), and other amines. In other words, although N₂ includes N as a compositional element of the molecules that constitute the gas, it is not classified as an N-based gas. The N-based gas is used as an impurity doping gas.

An “other impurity doping gas” (not shown in the drawings) is an impurity doping gas other than an N-based gas or a Cl-based gas. Examples thereof include N₂ and trimethylaluminum (TMA) and the like.

An “other gas” is a gas that does not correspond with any of the above five definitions. Examples thereof include Ar, He and H₂. These gases support the production of the SiC epitaxial wafer. This type of “other gas” can be used as a carrier gas that supports the flow of other gases so as to enable efficient supply of the raw material gases to the SiC wafer.

Among these gases, when a basic N-based gas and an acidic Cl-based gas are mixed, a chemical reaction occurs and a solid product is produced. For example, when ammonia as the N-based gas and hydrogen chloride as the Cl-based gas are mixed, ammonium chloride (NH₄Cl) is formed. Alternatively, when methylamine (CH₅N) as the N-based gas and hydrogen chloride as the Cl-based gas are mixed, monomethylamine hydrochloride (CH₅N.HCl) is formed. Moreover, it has also been reported that when ammonia as the N-based gas and dichlorosilane as the Cl-based gas are mixed, ammonium chloride is formed. The sublimation temperature of ammonium chloride is 338° C., whereas the melting point of monomethylamine hydrochloride is 220 to 230° C. and the boiling point is 225 to 230° C. In other words, at normal temperatures of 60° C. or lower, these solid products are produced.

In the chemical vapor deposition device 100, each of these gases is supplied individually from a gas supply device (omitted from the drawing) to the respective supply line 1. A high-purity gas supplied from a gas cylinder or a gas tank is supplied to the supply line 1. Accordingly, a separate supply line 1 is usually provided for each of the gases used in production of the SiC epitaxial wafer. In the case of gases that do not product a solid product upon mixing, a plurality of gases may also be supplied using a single supply line 1.

Each of the gases supplied to a supply line 1 reaches a corresponding valve 5. The valve switches whether to pass the gas to run line 3 side or to the gas to vent line 4 side. When it is necessary to supply the gas to the reactor 20, the gas is fed to the run line 3, whereas when supply is unnecessary, the gas is fed to the vent line 4.

The gases that flow through the run line 3 react inside the reactor 20, and are discharged from the exhaust pump 30 through the exhaust line 2. Further, the gases that flow through the vent lines 4 flow straight into the exhaust line 2, and are discharged from the exhaust pump 30. By using the run-vent mode, gases can be supplied to the reactor by switching the valves 5, with the flow rates of the gases flowing through the supply lines 1 maintained at constant levels. As a result, the amount of gas supplied from the supply lines 1 is stable from the beginning of gas flow into the reactor, and any fluctuations in the flow rate of supplied gas caused by switching of the gases can be suppressed. By suppressing any fluctuations in the gas flow rate and the gas pressure of the supplied gases, crystal growth of the epitaxial film is prevented from becoming unstable.

A specific description is provided below of the case where neither an N-based gas nor a Cl-based gas is supplied to the reactor 20 at a certain timing during the production process for the SiC epitaxial wafer.

When neither an N-based gas nor a Cl-based gas is supplied to the reactor 20, the N-based gas (reference sign G1) and the Cl-based gas (reference sign G2) supplied from the supply lines 1 are both controlled by the corresponding valves 5 and fed into the vent lines 4.

In the gas piping system 10 illustrated in FIG. 1, a separate vent line 4 is provided for each gas. Accordingly, the N-based gas and the Cl-based gas undergo no mixing until reaching the exhaust line 2. Provided the N-based gas and the Cl-based gas undergo no mixing, production of solid products will also not occur within the vent lines 4, meaning blockages of the vent lines 4 do not occur.

In contrast, in a gas piping system 11 of a chemical vapor deposition device 101 illustrated in FIG. 2, the vent lines 14 merge before reaching the exhaust line 2. Consequently, the N-based gas and the Cl-based gas mix inside the vent line 14, and a solid product is formed. As a result, the vent lines 14 can become blocked. The gas supply portion is typically positioned upstream of the reactor, and the distance to the reactor is generally short, but the vent lines are typically piped to the downstream side of the reactor, and because they are often longer than the lines of the run line side, blockages can occur easily. Further, the vent lines 14 are often formed using narrow piping with an inner diameter of ¼ inch (9.2 mm) or ⅜ inch (12.7 mm), meaning blockages can occur easily.

If a vent line 14 becomes blocked, then the conductance of the vent line 14 falls, and a difference develops in the ease of gas flow between the run line 3 and the vent line 14. In other words, the run-vent mode, which has the purpose of suppressing fluctuations in the gas flow velocity and pressure, becomes dysfunctional. Furthermore, in some cases, if the vent line 14 becomes completely blocked, then a situation in which gas is no longer able to flow through the vent line 14 is also possible.

On the other hand, in the gas piping system 10 according to the embodiment of the present disclosure, the N-based gas and the Cl-based gas merge inside the exhaust line 2. Accordingly, there is a possibility that blockage of the exhaust line 2 may occur. However, the exhaust line 2 must also exhaust the gas from inside the reactor 20, and therefore a thicker pipe than the vent lines 4 is used. Further, because the exhaust line 2 is evacuated directly by the exhaust pump 30, the gas flow velocity is higher than in the vent lines 4. As a result, the chance of solid products being produced in an amount sufficient to block the exhaust line 2, so that the conductance of the exhaust line 2 varies sufficiently to cause adverse effects, is considered unlikely in normal usage.

Further, in order to better suppress the deposit of solid products inside the exhaust line 2, the pipe inner diameter of the exhaust line 2 at the connection points with the vent lines 4 is preferably 3 cm or greater. In terms of the ratio between the inner diameters of the pipes, the pipe inner diameter of the exhaust line 2 is preferably at least 5 times as large as the pipe inner diameter of the vent lines 4. Furthermore, in an exhaust line 2 into which a plurality of vent lines 4 merge, the gas concentration of the N-based gas and the Cl-based gas that act as deposit-causing gases is preferably not more than 5% of the total of gas flowing through the exhaust line 2.

As described above, in the chemical vapor deposition device 100 according to the first embodiment, no mixing of deposit-causing gases occurs inside the vent lines 4, and no blockages of the vent lines 4 occur. Provided the vent lines 4 do not become blocked, fluctuations in the gas flow velocity and pressure can be suppressed across the entire chemical vapor deposition device 100, and high-quality films can be produced with good stability. Further, the amount of gas fed through the vent lines 4 may be set freely, and the degree of freedom associated with the settings for controlling the chemical vapor deposition device 100 can be enhanced.

### Second Embodiment

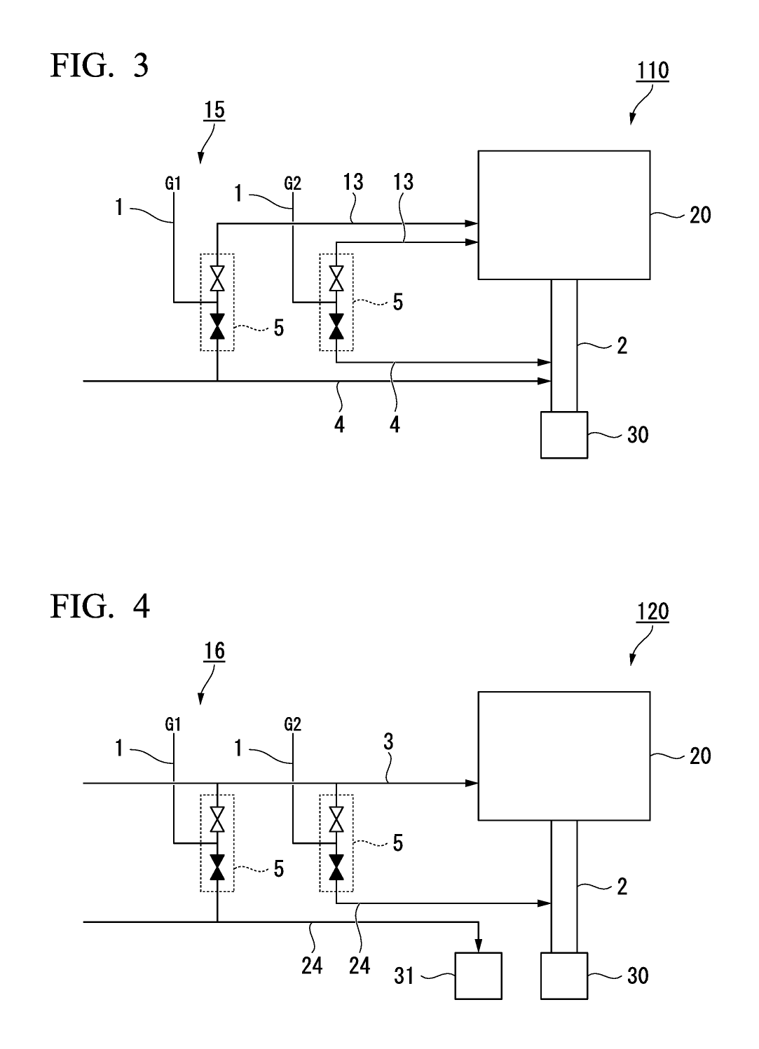

FIG. 3 is a schematic view of a chemical vapor deposition device 110 according to the second embodiment. A gas piping system 15 in the chemical vapor deposition device 110 according to this second embodiment differs in that the run lines 13 are separated until reaching the reactor 20. Other structures are the same as those of the chemical vapor deposition device 100 of the first embodiment, and those structures that are the same are labeled with the same reference signs.

When the run lines 13 are mutually separated, mixing of deposit-causing gases inside the run lines 13 can be avoided. In other words, blockages of the run lines 13 can be suppressed. On the other hand, when the run lines 13 are separated, timing lags are more likely to occur in supplying the necessary gases to the reactor 20 than in the chemical vapor deposition device 100 of the first embodiment.

Accordingly, whether to use the chemical vapor deposition device 100 according to the first embodiment or the chemical vapor deposition device 110 according to the second embodiment is preferably determined appropriately in accordance with the object to be crystal grown and the types of gases being used and the like. Typically, the run line flowing into the reactor 20 during epitaxial growth is prioritized when determining the gas flow rate program. Accordingly, settings for the run line may also be made so as to prioritize controls of the run line such as gas switching that suppresses blockages, meaning that, compared with the vent lines, blockages of the run line can be more easily prevented from occurring. In contrast, by employing the vent lines of the gas piping system according to the embodiments described above, the conditions on the run line side can be set without having to consider blockages on the vent line side. Moreover, by using the gas piping system according to the second embodiment, any restrictions on the run line side are also reduced, meaning the conditions for the epitaxial growth can be set with more freedom.

### Third Embodiment

FIG. 4 is a schematic view of a chemical vapor deposition device 120 according to the third embodiment. A gas piping system 16 in the chemical vapor deposition device 120 according to this third embodiment differs in that a part of the vent lines 24 are connected to the exhaust line 2, whereas the remaining vent lines 24 are connected to a separate exhaust pump 31 that is provided independently. Other structures are the same as those of the chemical vapor deposition device 100 of the first embodiment, and those structures that are the same are labeled with the same reference signs.

In the chemical vapor deposition device 120 according to the third embodiment, deposit-causing gases do not merge even in the exhaust line 2. In other words, deposit-fonning gases are completely separated from each other from the time of supply to the gas piping system 16 until discharge from the system. Accordingly, the production of solid products due to mixing of deposit-causing gases cannot occur.

On the other hand, a plurality of exhaust pumps must be provided. This raises the problems of space and cost for installing the exhaust pumps. Accordingly, whether to use the chemical vapor deposition device 100 according to the first embodiment or the chemical vapor deposition device 120 according to the third embodiment is preferably determined appropriately in accordance with factors such as the environment in which the chemical vapor deposition device is to be installed, and the number of exhaust pumps that can be provided.

Preferred embodiments of the present invention have been described above in detail, but the present invention is not limited to these specific embodiments, and various modifications and alterations are possible within the scope of the present invention as disclosed within the claims.

Furthermore, the description up until this point has used the production of a SiC epitaxial wafer as an example, but the present invention is not limited to this application, and the chemical vapor deposition devices according to the embodiments described above can also be used in producing other films.

### DESCRIPTION OF THE REFERENCE SIGNS

1: Supply line
2: Exhaust line
3: Run line
4, 14, 24: Vent line
5: Valve
10, 11, 15, 16: Gas piping system
20: Reactor
30, 31: Exhaust pump
100, 101, 110, 120: Chemical vapor deposition device

1. A run-vent mode gas piping system in which a plurality of gases are supplied to an inside of a reactor in which vapor deposition is performed, the gas piping system comprising:
a plurality of supply lines through which the plurality of gases are fed individually,
an exhaust line that leads from an exhaust port of the reactor to an exhaust pump,
a run line which has one or a plurality of pipes which respectively branch from the plurality of supply lines to supply the plurality of gases to the reactor,
a plurality of vent lines which respectively branch from the plurality of supply lines and are connected to the exhaust line, and
a plurality of valves which are respectively provided at branch points of the plurality of supply lines, and switches between feeding a gas to the run line side and feeding a gas to the vent line side, wherein
the plurality of vent lines are separated from each other until the vent lines reach the exhaust line, and an inner diameter of the exhaust line is greater than an inner diameter of each of the plurality of vent lines.

2. The gas piping system according to claim 1, wherein the pipes, which connect with the branch points, join together before the pipes reach the reactor.

3. The gas piping system according to claim 1, wherein among the plurality of vent lines, at least one vent line is connected to the exhaust line, and remaining vent lines are each connected to a separate exhaust pump which is provided independently.

4. The gas piping system according to claim 1, wherein a pipe inner diameter of the exhaust line is 3 cm or greater at connection points where the exhaust line connect with each of the plurality of vent lines.

5. A chemical vapor deposition device comprising the gas piping system according to claim 1, and a reactor that is connected to the gas piping system.

6. A film deposition method that uses the chemical vapor deposition device according to claim 5, the method comprising
sending deposit-causing gases, which produce a solid compound upon mutual reaction at normal temperature, through the vent lines which are independent and are mutually separated.

7. The film deposition method according to claim 6, wherein regarding the exhaust line to which the plurality of vent lines connect, a gas concentration of each of the deposit-causing gases is 5% or less of that of total gas which flows through the exhaust line.

8. A method for producing a SiC epitaxial wafer using the film deposition method according to claim 6, wherein
the deposit-causing gases are a basic N-based gas composed of molecules which include an N atom within each molecule but have neither a double bond nor a triple bond between N atoms, and a Cl-based gas composed of molecules which include a Cl atom within each molecule.
